(19) United States
(12) Patent Application Publication
(10) Pub. No.: US 2015/0179802 A1
(43) Pub. Date: Jun. 25, 2015

(54) THIN FILM TRANSISTOR, DISPLAY SUBSTRATE HAVING THE SAME AND METHOD OF MANUFACTURING A DISPLAY SUBSTRATE

(71) Applicant: SAMSUNG DISPLAY CO., LTD., Yongin-City (KR)

(72) Inventors: Jae-Neung Kim, Seoul (KR); Shin-Il Choi, Hwaseong-si (KR); Yu-Gwang Jeong, Anyang-si (KR); Su-Bin Bae, Gyeongsan-si (KR); Dae-Ho Kim, Daegu (KR); Sang-Gab Kim, Seoul (KR)

(21) Appl. No.: 14/527,632

(22) Filed: Oct. 29, 2014

(30) Foreign Application Priority Data
Dec. 20, 2013 (KR) 10-2013-0160740

(51) Int. Cl. H01L 29/786; H01L 29/66; H01L 27/12

(52) U.S. Cl. CPC H01L 29/7869; H01L 27/124; H01L 29/66742; H01L 27/1225; H01L 27/1259

(57) ABSTRACT

A thin film transistor includes a gate electrode, an active pattern over the gate electrode and including an oxide semiconductor, an etch-stop layer covering the active pattern, a source electrode on the etch-stop layer, a drain electrode on the etch-stop layer and spaced from the source electrode, and an active protection pattern between the etch-stop layer and the active pattern and electrically coupled to the source electrode and the drain electrode.

### CROSS-REFERENCE TO RELATED APPLICATION

This application claims priority to and the benefit of Korean Patent Application No. 10-2013-0160740, filed on Dec. 20, 2013 in the Korean Intellectual Property Office, the content of which is herein incorporated by reference in its entirety.

### BACKGROUND

1. Field

Aspects of embodiments of the present invention relate to a thin film transistor.

2. Description of the Related Art

Generally, a thin film transistor for driving a pixel unit in a display device includes a gate electrode, a source electrode, a drain electrode, and an active pattern forming a channel between the source electrode and the drain electrode. The active pattern includes a semiconductor layer including amorphous silicon, polycrystalline silicon, oxide semiconductor, or the like.

Amorphous silicon has a relatively low electron mobility, which may be in a range of about 1 to about 10 cm²/V, so that a thin film transistor including amorphous silicon has relatively low driving characteristics. In contrast, polycrystalline silicon has a relatively high electron mobility, which may be in a range of about 10 to about hundreds cm²/V. However, a crystallization process is required for forming polycrystalline silicon. Thus, it is difficult to form a uniform polycrystalline silicon layer on a large-sized substrate, and resulting manufacturing costs are high. Oxide semiconductors may be formed through a low-temperature process, may be easily formed in a large-scale, and have a high electron mobility. Thus, research is actively being conducted on thin film transistors which include an oxide semiconductor.

When a display substrate including an oxide semiconductor channel is manufactured, an etch-stop layer may be formed on the oxide semiconductor channel to prevent damage to the oxide semiconductor channel. However, in the process of forming a contact opening (e.g., a contact hole) of the etch-stop layer, the oxide semiconductor channel may be damaged, thereby causing deterioration of electrical characteristics and reliability of a thin film transistor.

### SUMMARY

Aspects of example embodiments provide a thin film transistor having improved reliability and electrical characteristics.

Aspects of example embodiments also provide a display substrate including the thin film transistor.

Aspects of example embodiments also provide a method of manufacturing a display substrate.

According to an example embodiment, a thin film transistor includes a gate electrode, an active pattern over (e.g., overlapping) the gate electrode and including an oxide semiconductor, an etch-stop layer covering the active pattern, a source electrode on the etch-stop layer, a drain electrode on the etch-stop layer and spaced from (e.g., spaced apart from) the source electrode, and an active protection pattern between the etch-stop layer and the active pattern and electrically coupled to (e.g., electrically connected to) the source electrode and the drain electrode.

In an embodiment, the active protection pattern may include a conductive oxide.

In an embodiment, the active pattern may cover an entire lower surface of the active protection pattern.

In an embodiment, the active protection pattern may include, a first active protection pattern over the source electrode, and a second active protection pattern over the drain electrode.

In an embodiment, the source electrode may include a source contact extending (e.g., passing) through the etch-stop layer to contact the first active protection pattern. The drain electrode may include a drain contact extending through the etch-stop layer to contact the second active protection pattern. A distance between the first active protection pattern and the second active protection pattern may be smaller than a distance between the source contact and the drain contact.

According to an example embodiment, a display substrate includes a gate line on a base substrate, a data line crossing the gate line, a first gate electrode electrically coupled to the gate line, a first active pattern over the first gate electrode and including an oxide semiconductor, an etch-stop layer covering the first active pattern, a first source electrode on the etch-stop layer and electrically coupled to the data line, a first drain electrode on the etch-stop layer and spaced from the first source electrode, and an active protection pattern between the etch-stop layer and the active pattern and electrically coupled to the first source electrode and the first drain electrode.

According to an example embodiment, a method for manufacturing a display substrate is provided. The method includes forming a gate metal pattern on a base substrate. The gate metal pattern includes a gate electrode. Forming a gate insulation layer covering the gate metal pattern. Forming an active pattern and an active protection pattern on the gate insulation layer. The active pattern includes an oxide semiconductor, and the active protection pattern is on the active pattern. Forming an etch-stop layer covering the active protection pattern. Patterning the etch-stop layer to expose the active protection pattern. Forming a source metal pattern, including a source electrode and a drain electrode, to contact the active protection pattern.

According to the example embodiments, an active protection pattern is formed between an etch-stop layer and an active pattern. Thus, the active pattern may not be damaged during the process of etching the etch-stop layer.

Furthermore, the active protection pattern may substantially reduce a channel length to improve characteristics of a thin film transistor.

Furthermore, the active protection pattern may be formed without an additional mask.

### BRIEF DESCRIPTION OF THE DRAWINGS

The above and other features and characteristics will become more apparent by describing example embodiments thereof with reference to the accompanying drawings, in which:

FIG. 1 is a plan view illustrating a display substrate according to an example embodiment.

FIG. 2 is a cross-sectional view taken along the a line I-I′ of FIG. 1.

FIG. 3 is a cross-sectional view taken along the line a II-II′ of FIG. 1.

FIGS. 4 to 14 are cross-sectional views illustrating a method for manufacturing the display substrate illustrated in FIGS. 1 to 3.

FIGS. 15 to 25 are cross-sectional views illustrating a method for manufacturing the display substrate according to another example embodiment.

FIG. 26 is a plan view illustrating a display substrate according to another example embodiment.

FIG. 27 is a cross-sectional view taken along the a line I-I′ of FIG. 26.

FIGS. 28 to 36 are cross-sectional views illustrating a method for manufacturing the display substrate illustrated in FIGS. 26 and 27.

### DETAILED DESCRIPTION

It will be understood that when an element or layer is referred to as being “on”, “connected to”, or “coupled to” another element or layer, it may be directly on, connected, or coupled to the other element or layer or one or more intervening elements or layers may also be present. When an element is referred to as being “directly on”, “directly connected to”, or “directly coupled to” another element or layer, there are no intervening elements or layers present. As used herein, the term “and/or” includes any and all combinations of one or more of the associated listed items. Further, the use of “may” when describing embodiments of the present invention relates to “one or more embodiments of the present invention”.

It will be understood that, although the terms first, second, third, etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing particular example embodiments only and is not intended to be limiting of example embodiments. As used herein, the singular forms “a”, “an”, and “the” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The same reference numerals designate the same elements.

Example embodiments will be described more fully hereinafter with reference to the accompanying drawings, in which various embodiments are shown.

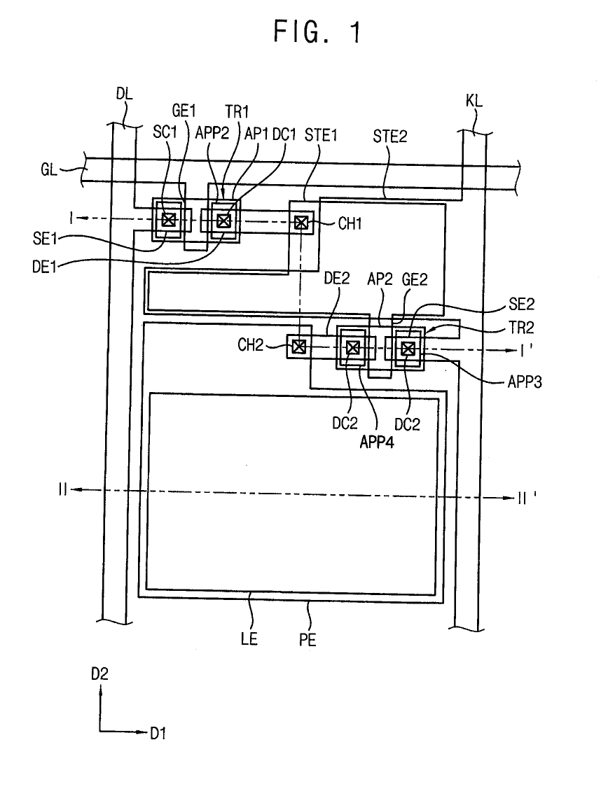

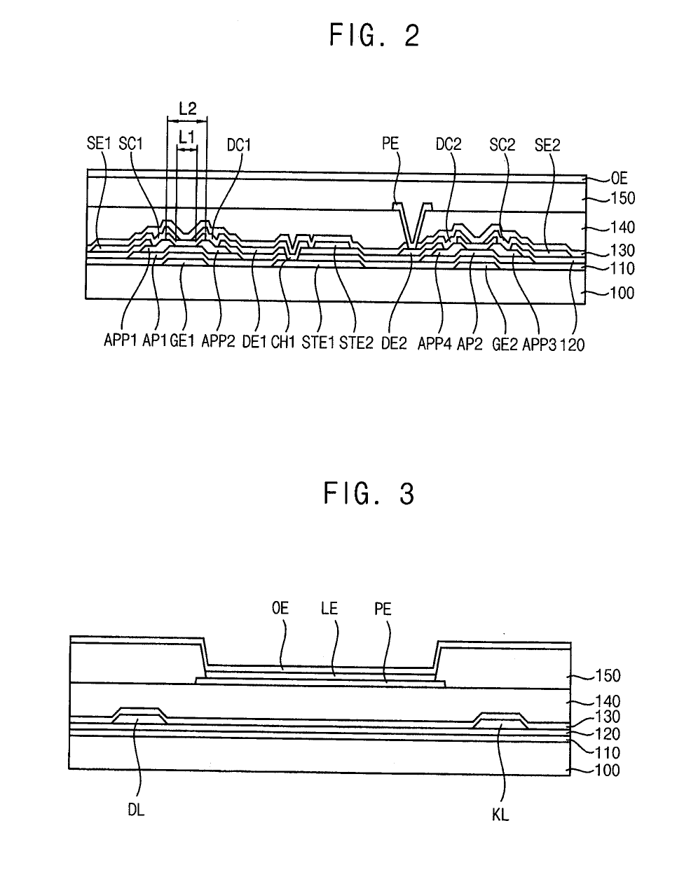

FIG. 1 is a plan view illustrating a display substrate according to an example embodiment. FIG. 2 is a cross-sectional view taken along a line I-I′ of FIG. 1. FIG. 3 is a cross-sectional view taken along a line II-II′ of FIG. 1.

Referring to FIGS. 1 to 3, a display substrate includes a base substrate 100, a switching transistor TR1 on the base substrate 100, a driving transistor TR2 on the base substrate 100, a pixel electrode PE electrically coupled to (e.g., electrically connected to) the driving transistor TR2, a light-emitting layer LE receiving a current from the pixel electrode PE to generate light, and an opposing electrode OE disposed on the light-emitting layer LE. The display substrate may be used for an organic electroluminescence display device.

The switching transistor TR1 is electrically coupled to a gate line GL and a data line DL. The switching transistor TR1 includes a first gate electrode GE1, a first active pattern AP1, a first source electrode SE1, and a first drain electrode DE1.

The gate line GL extends in a first direction D1, and the data line DL extends in a second direction D2, in a plan view. The first direction D1 crosses (e.g., intersects) the second direction D2. For example, the first direction D1 may be substantially perpendicular to the second direction D2.

The gate line GL is electrically coupled to the first gate electrode GE1. For example, the first gate electrode GE1 may protrude from the gate line GL in the second direction D2. In another embodiment, a portion of the gate line GL may overlap the first active pattern AP1 to function as the first gate electrode GE1 so that the first gate electrode GE1 may not protrude from the gate line GL.

The display substrate further includes a gate insulation layer 110 covering the first gate electrode GE1 and the gate line GL.

The first active pattern AP1 overlaps the first gate electrode GE1. The first active pattern AP1 is disposed on the gate insulation layer 110. The first active pattern AP1 includes an oxide semiconductor. When a gate voltage is applied to the first gate electrode GE1, the first active pattern AP1 becomes a conductor to function as a channel.

The display substrate further includes an etch-stop layer 120 covering the first active pattern AP1.

The first source electrode SE1 and the first drain electrode DE1 are spaced from (e.g., spaced apart from) each other and are each electrically coupled to the first active pattern AP1. The first source electrode SE1 and the first drain electrode DE1 are disposed on the etch-stop layer 120.

An active protection pattern is disposed between the first active pattern AP1 and the first source electrode SE1 and/or between the first active pattern AP1 and the first drain electrode DE1. For example, a first active protection pattern APP1 is disposed between the first source electrode SE1 and the first active pattern AP1, and a second active protection pattern APP2 is disposed between the first drain electrode DE1 and the first active pattern AP1. The etch-stop layer 120 has a plurality of contact openings (e.g., contact holes). A first source contact SC1 of the first source electrode SE1 and a first drain contact DC1 of the first drain electrode DE1 pass through respective contact openings of the etch-stop layer 120 to respectively contact the first active protection pattern APP1 and the second active protection pattern APP2.

The first and second active protection patterns APP1 and APP2 are disposed under the etch-stop layer 120. Thus, the first active pattern AP1 is not exposed through the contact openings of the etch-stop layer 120.

The first and second active protection patterns APP1 and APP2 are conductive. For example, the first and second active protection patterns APP1 and APP2 may include a metal, a conductive oxide, or the like. For example, the first and second active protection patterns APP1 and APP2 may include a conductive oxide such as indium zinc oxide, indium tin oxide, gallium zinc oxide, zinc aluminum oxide, or the like.

The first and second active protection patterns APP1 and APP2 and the first active pattern AP1 may be formed through a same photolithography process. As a result, the first active pattern AP1 covers an entire lower surface of the first and second active protection patterns APP1 and APP2. Thus, an outline of the first active pattern AP1 may have a shape surrounding the first and second active protection patterns APP1 and APP2.

In another embodiment, the first and second active protection patterns APP1 and APP2 may be formed through a photolithography different from that which forms the first active pattern AP1, so that the first active pattern AP1 partially covers a lower surface of the first and second active protection patterns APP1 and APP2.

The first and second active protection patterns APP1 and APP2 cover the first active pattern AP1 to protect the first active pattern AP1 from damage that may be caused in the process of forming the contact openings of the etch-stop layer 120.

When the first and second active protection patterns APP1 and APP2 are not formed, a channel length may be defined by a length between the contact openings of the etch-stop layer 120, which is a length L2 between the first source contact SC1 and the first drain contact DC1. However, when the first and second active protection patterns APP1 and APP2 are formed, a channel length may be defined by a length L1 between the first and second active protection patterns APP1 and APP2, which is smaller than (less than) the length L2 between the first source contact SC1 and the first drain contact DC1. Thus, a thin film transistor may have a reduced channel length, which may improve electrical characteristics of the thin film transistor.

The data line DL is electrically coupled to the first source electrode SE1. For example, the first source electrode SE1 may protrude from the data line DL in the first direction D1. The data line DL may be formed at a same layer as the first source electrode SE1 and the first drain electrode DE1. In another embodiment, a portion of the data line DL may contact the first active pattern AP1 or the first active protection pattern APP1 to function as the first source electrode SE1 so that the first source electrode SE1 may not protrude from the data line DL.

The first drain electrode DE1 is electrically coupled to the driving transistor TR2. The driving transistor TR2 includes a second gate electrode GE2, a second active pattern AP2, a second source electrode SE2, and a second drain electrode DE2.

The second gate electrode GE2 may be disposed at a same layer as the first gate electrode GE1. The second active pattern AP2 may be disposed at a same layer as the first active pattern AP1. The second source electrode SE2 and the second drain electrode DE2 may be disposed at a same layer as the first source electrode SE1 and the first drain electrode DE1. Thus, the gate insulation layer 110 covers the second gate electrode GE2, and the etch-stop layer 120 covers the second active pattern AP2.

The first drain electrode DE1 is electrically coupled to the second gate electrode GE2. For example, the first drain electrode DE1 contacts a first capacitor electrode STE1. A portion of the first capacitor electrode STE1 forms the second gate electrode GE2. The first capacitor electrode STE2 may be disposed at a same layer as the first gate electrode GE1. Thus, the gate insulation layer 110 and the etch-stop layer 120 are disposed on the first capacitor electrode STE1. The first drain electrode DE1 contacts the first capacitor electrode STE1 through a first contact portion CH1 (e.g., first contact opening) that passes through the gate insulation layer 110 and the etch-stop layer 120 so that the first drain electrode DE1 is electrically coupled to the second gate electrode GE2.

The display substrate further includes a second capacitor electrode STE2 disposed at a layer different from that of the first capacitor electrode STE1 and overlapped with the first capacitor electrode STE1. In an embodiment, the second capacitor electrode STE2 may be disposed at a same layer as the second source electrode SE2 and the second drain electrode DE2. The first capacitor electrode STE1 and the second capacitor electrode STE2 form a capacitor charged depending on voltages applied thereto.

The second source electrode SE2 is electrically coupled to a driving line KL. A current provided from the driving line KL is applied to the light-emitting layer LE through the driving transistor TR2 and the pixel electrode PE. The driving line KL may be disposed at a same layer as the second source electrode SE2 and the second capacitor electrode STE2.

An active protection pattern is disposed between the second active pattern AP2 and the second source electrode SE2 and/or between the second active pattern AP2 and the second drain electrode DE2. For example, a third active protection pattern APP3 is disposed between the second source electrode SE2 and the second active pattern AP2, and a fourth active protection pattern APP4 is disposed between the second drain electrode DE2 and the second active pattern AP2. The etch-stop layer 120 has a plurality of contact openings (e.g., contact holes). A second source contact SC2 of the second source electrode SE2 and a second drain contact DC2 of the second drain electrode DE2 respectively contact the third active protection pattern APP3 and the fourth active protection pattern APP4 through respective contact openings of the etch-stop layer 120.

The third and fourth active protection patterns APP3 and APP4 are disposed under the etch-stop layer 120. Thus, the second active pattern AP2 is not exposed through the contact openings of the etch-stop layer 120.

The display substrate further includes a passivation layer 130 covering the switching transistor TR1 and the driving transistor TR2, an organic insulation layer 140 covering the passivation layer 130 and flattening the substrate (e.g., having a planar surface), and a partition layer 150 disposed on the organic insulation layer 140.

The pixel electrode PE is disposed on the organic insulation layer 140 and passes through the passivation layer 130 and the organic insulation layer 140 to contact the second drain electrode DE2.

The partition layer 150 is disposed on the organic insulation layer 140 and has an opening overlapping with the pixel electrode PE. The light-emitting layer LE is disposed in the opening. The opposing electrode OE may be disposed continuously on the light-emitting layer LE and the partition layer 150 (e.g., that opposing electrode OE may be disposed over an entirety of the light-emitting layer LE and the partition layer 150).

The light-emitting layer LE may have the same layers as a light-emitting layer of a conventional organic electroluminescence display device. For example, the light-emitting layer LE may include a hole-transferring layer, a hole-injection layer, an organic light-emitting layer, an electron-injection layer, an electron-transferring layer, and may further include various functional layers.

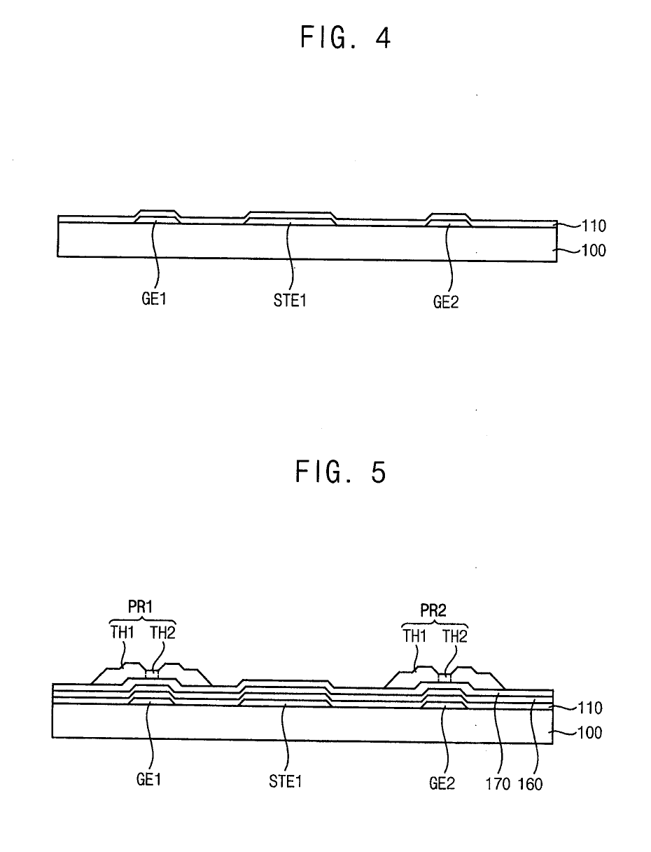

FIGS. 4 to 14 are cross-sectional views illustrating a method for manufacturing the display substrate illustrated in FIGS. 1 to 3.

Referring to FIG. 4, a gate metal layer is formed on a base substrate 100 and is patterned to form a gate metal pattern including a first gate electrode GE1, a second gate electrode GE2, and a first capacitor electrode STE1. The second gate electrode GE2 and the first capacitor electrode STE2 are coupled to (e.g., connected or continuously connected to) each other (e.g., are integrally formed). The gate metal pattern may further include a gate line coupled to (e.g., connected, continuously connected to, or integrally formed with) the first gate electrode GE1.

Examples of the base substrate 100 may include a glass substrate, a quartz substrate, a silicon substrate, a plastic substrate, or the like.

Examples of a material that may be used for the gate metal layer may include copper, silver, chromium, molybdenum, aluminum, titanium, manganese, or an alloy thereof. The gate metal layer may have a single-layered structure or may have a multiple-layered structure including different materials. For example, the gate metal layer may include a copper layer and a titanium layer disposed on and/or under the copper layer.

In another embodiment, the gate metal layer may include a metal layer and a conductive oxide layer disposed on and/or under the metal layer. For example, the gate metal layer may include a copper layer and a conductive oxide layer disposed on and/or under the copper layer. Examples of a material that may be used for the conductive oxide layer may include indium zinc oxide, indium tin oxide, gallium zinc oxide, and zinc aluminum oxide.

Thereafter, a gate insulation layer 110 is formed to cover the gate metal pattern. Examples of a material that may be used (utilized) for the gate insulation layer 110 may include silicon nitride, silicon oxide, aluminum oxide, hafnium oxide, titanium oxide, and the like. The gate insulation layer 110 may have a single-layered structure or a multiple-layered structure. For example, the gate insulation layer 110 may include a lower insulation layer including silicon nitride and an upper insulation layer including silicon oxide.

Referring to FIG. 5, an oxide semiconductor layer 160 and an active protection layer 170 are formed on the gate insulation layer 110.

Examples of a material that may be used for the oxide semiconductor layer 160 may include zinc oxide, zinc tin oxide, indium zinc oxide, indium oxide, titanium oxide, indium gallium zinc oxide, indium zinc tin oxide, and the like. In an embodiment, the oxide semiconductor layer 160 includes indium zinc tin oxide.

The active protection layer 170 may include a metal, a conductive oxide, or the like. For example, the active protection layer 170 may include a conductive oxide (such as indium zinc oxide, indium tin oxide, gallium zinc oxide, zinc aluminum oxide, or the like).

A first photoresist pattern PR1 and a second photoresist pattern PR2 are formed on the active protection layer 170. The first and second photoresist patterns PR1 and PR2 have thickness gradient (e.g., have a thickness that varies or gradually varies). For example, the first and second photoresist patterns PR1 and PR2, respectively, include a first thickness portion TH1 and a second thickness portion TH2 that is thinner than the first thickness portion TH1.

For example, a photoresist composition is coated (e.g., deposited), exposed to a light through a half-tone exposure, and developed by a developing solution to form the first and second photoresist patterns PR1 and PR2.

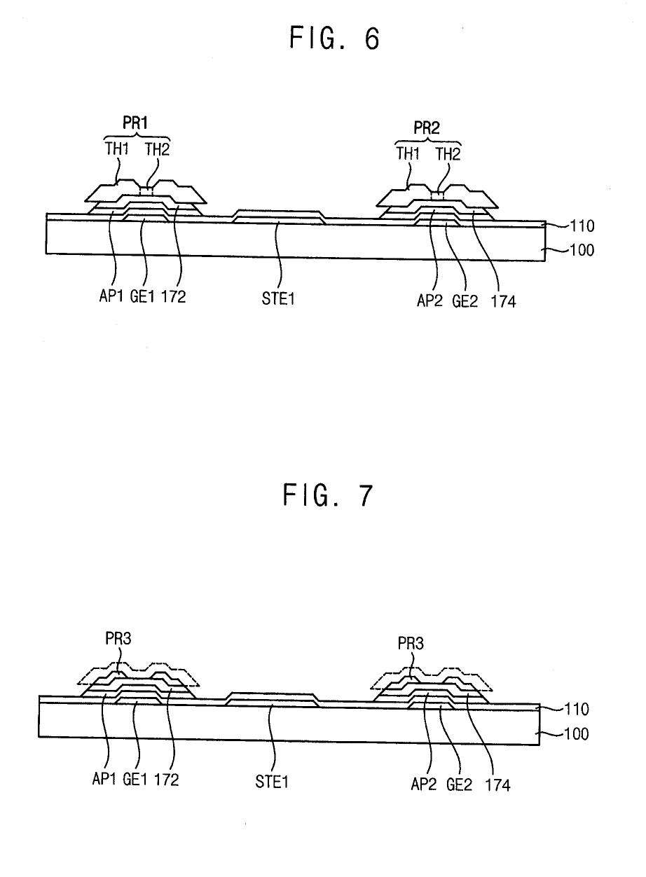

Referring to FIG. 6, the oxide semiconductor layer 160 and the active protection layer 170 are etched by using (utilizing) the first and second photoresist patterns PR1 and PR2 as a mask to form a first active pattern AP1, a second active pattern AP2, a first preliminary active protection pattern 172, and a second preliminary active protection pattern 174.

The first active pattern AP1 overlaps with the first gate electrode GE1. The first preliminary active protection pattern 172 is disposed on the first active pattern AP1. The second active pattern AP2 overlaps with the second gate electrode GE2. The second preliminary active protection pattern 174 is disposed on the second active pattern AP2.

Referring to FIG.7, the first and second photoresist patterns PR1 and PR2 are partially removed through an ashing process. As a result, the second thickness portion TH2 of the first and second photoresist patterns PR1 and PR2 and the first thickness portion TH1 of the first and second photoresist patterns PR1 and PR2 partially remain to form a third photoresist pattern PR3 and a fourth photoresist pattern PR4.

The third photoresist pattern PR3 covers a portion of an upper surface of the first preliminary active protection pattern 172. The third photoresist pattern PR4 covers a portion of an upper surface of the second preliminary active protection pattern 174.

Thus, the upper surfaces of the first and second preliminary active protection patterns 172 and 174 are partially exposed.

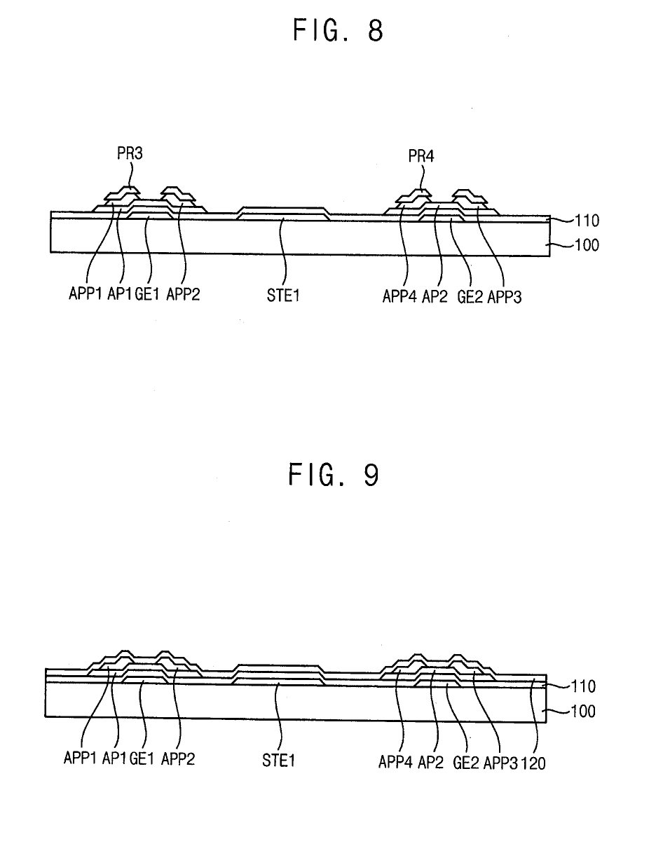

Referring to FIG. 8, the first and second preliminary active protection patterns 172 and 174 are etched by using (utilizing) the third and fourth photoresist patterns PR3 and PR4 as a mask to form a first active protection pattern APP1, a second active protection pattern APP2, a third active protection pattern APP3, and a fourth active protection pattern APP4. For example, the first and second preliminary active protection patterns 172 and 174 may be etched through a dry etching process or a wet etching process.

The first and second active protection patterns APP1 and APP2 are disposed on the first active pattern AP1 and are spaced from each other. The third and fourth active protection patterns APP3 and APP4 are disposed on the second active pattern AP2 and are spaced from each other.

Referring to FIG. 9, an etch-stop layer 120 is formed to cover the first to fourth active protection patterns APP1, APP2, APP3, and APP4. A portion of the etch-stop layer 120 contacts the gate insulation layer 110. Examples of a material that may be included in the etch-stop layer 120 may include silicon nitride, silicon oxide, aluminum oxide, hafnium oxide, titanium oxide, and the like.

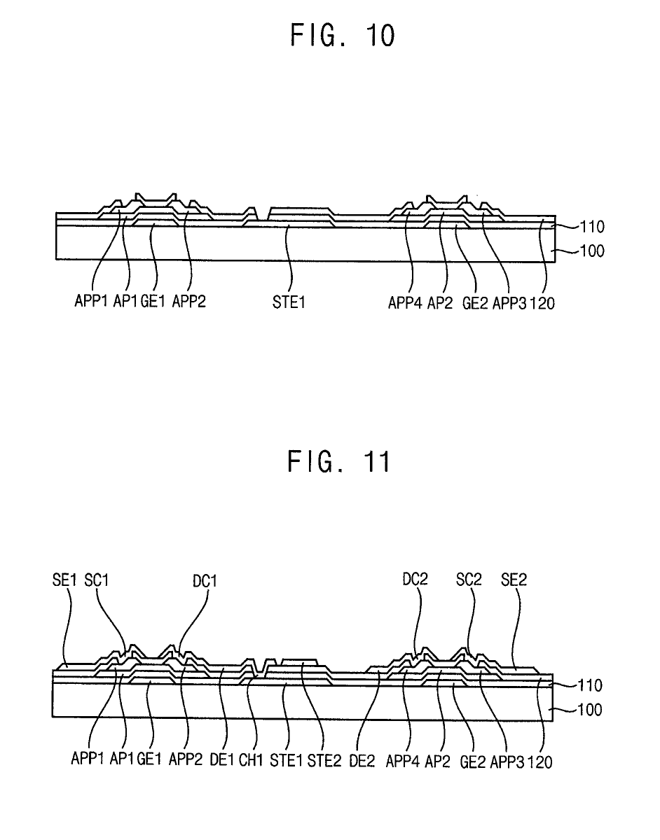

Referring to FIG. 10, the etch-stop layer 120 is patterned to form contact openings (e.g., contact holes) respectively exposing the first to fourth active protection patterns APP1, APP2, APP3, and APP4.

In a same process, the etch-stop layer 120 and the gate insulation layer 110 are patterned to expose the first capacitor electrode STE1.

During the process of exposing the first capacitor electrode STE1, over-etching of the etch-stop layer 120 occurs so that the gate insulation layer 110 may be etched (e.g., may be unintentionally etched). Thus, when the active protection patterns do not exist, the active patterns may be damaged. In an embodiment, the active protection patterns are formed on the active patterns so that damage to the active pattern is prevented.

Referring to FIG. 11, a source metal layer is formed on the etch-stop layer 120 and patterned to form a source metal pattern including a first source electrode SE1, a first drain electrode DE1, a second capacitor electrode STE2, a second source electrode SE2, and a second drain electrode DE2. The source metal pattern may further include a data line coupled to (e.g., connected, continuously connected to, or integrally formed with) the first source electrode SE1 and a driving line coupled to (e.g., connected, continuously connected to, or integrally formed with) the second source electrode SE2 and the second capacitor electrode STE2.

Examples of a material that may be included in the source metal layer may include copper, silver, chromium, molybdenum, aluminum, titanium, manganese, or an alloy thereof. The source metal layer may have a single-layered structure or may have a multiple-layered structure including different materials. For example, the source metal layer may include a copper layer and a titanium layer disposed on and/or under the copper layer.

In another embodiment, the source metal layer may include a metal layer and a conductive oxide layer disposed on and/or under the metal layer. For example, the source metal layer may include a copper layer and a conductive oxide layer disposed on and/or under the copper layer.

The first source electrode SE1, the first drain electrode DE1, the second source electrode SE, and the second drain electrode DE2 respectively contact the first active protection pattern APP1, the second active protection pattern APP2, the third active protection pattern APP3, and the fourth active protection pattern APP4 through the contact openings of the etch-stop layer 120.

For example, the first source electrode SE1 includes a first source contact SC1 contacting the first active protection pattern APP1. The first drain electrode DE1 includes a first drain contact DC1 contacting the second active protection pattern APP2. The second source electrodes SE2 includes a second source contact SC2 contacting the third active protection pattern APP3. The second drain electrode DE2 includes a second drain contact DC2 contacting the fourth active protection pattern APP4.

The first drain electrode DE1 further includes a first contact portion CH1 passing through the etch-stop layer 120 and the gate insulation layer 110 to contact the first capacitor electrode STE1.

The second capacitor electrode STE2 is formed on the etch-stop layer 120 and overlaps with the first capacitor electrode STE1.

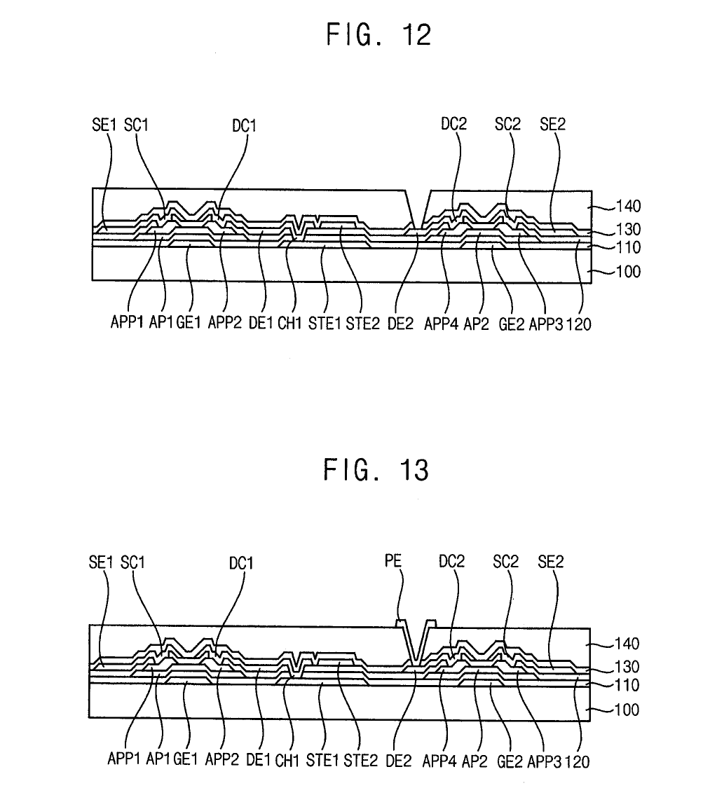

Referring to FIG. 12, a passivation layer 130 is formed to cover the source metal pattern. An organic insulation layer 140 is formed on the passivation layer 130.

The passivation layer 130 protects the source metal pattern. The organic insulation layer 140 flattens an upper surface of the substrate (e.g., the organic insulation layer 140 has a planar upper surface).

The passivation layer 130 may include silicon nitride, silicon oxide, or the like. The organic insulation layer 140 may include a polymer resin such as an acryl resin, a phenol resin, or the like.

The organic insulation layer 140 may be formed from a photoresist composition. The organic insulation layer 140 and the passivation layer 130 are patterned to form a contact opening (e.g., a contact hole) exposing the second drain electrode DE2.

Referring to FIG. 13, a pixel electrode layer is formed on the organic insulation layer 140 and patterned to form a pixel electrode PE. The pixel electrode PE includes a second contact portion CH2 passing through the organic insulation layer 140 and the passivation layer 130 to contact the second drain electrode DE2.

When the pixel electrode PE is used for (utilized as) an anode, the pixel electrode PE may include a metal oxide having a relatively good absolute value of a work function, such as indium zinc oxide, indium tin oxide, zinc oxide, or the like. When the pixel electrode PE is used for (utilized as) a cathode, the pixel electrode PE may include a metal having a relatively small absolute value of a work function, such as silver, magnesium, aluminum, platinum, lead, gold, nickel, neodymium, iron, chromium, lithium, calcium, or the like. When the pixel electrode PE is used for an anode, the opposing electrode OE is used for a cathode. When the pixel electrode PE is used for a cathode, the opposing electrode OE is used for an anode.

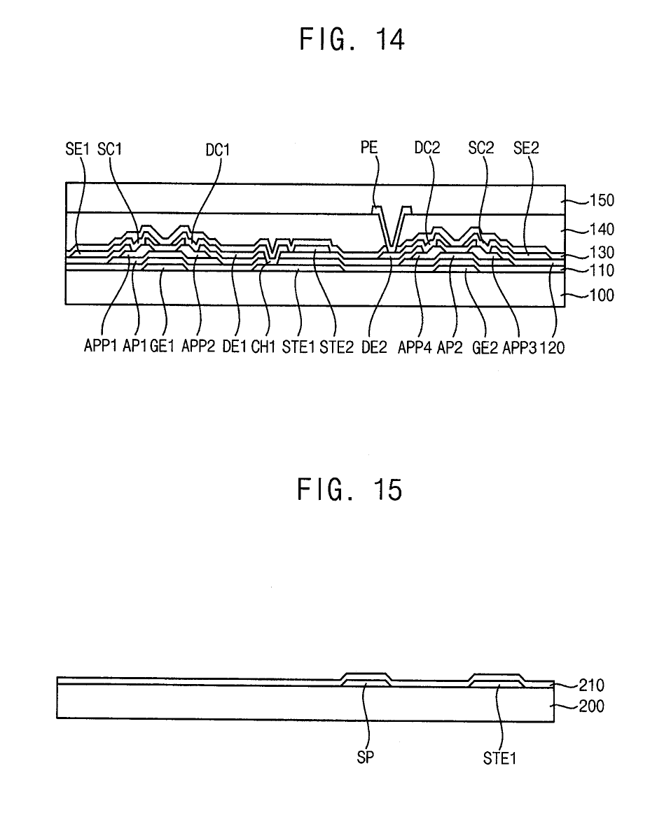

Referring to FIG. 14, a partition layer 150 is formed on the pixel electrode PE and the organic insulation layer 140. The partition layer 150 may include an organic insulation material.

As illustrated in FIG. 3, the partition layer 150 is patterned to form an opening exposing the pixel electrode PE. The opening may define a pixel area of each pixel unit.

A light-emitting layer LE is formed in the opening. The light-emitting layer LE may include a hole-transferring layer, a hole-injection layer, an organic light-emitting layer, an electron-injection layer, an electron-transferring layer, and may further include various functional layers.

The opposing electrode OE is formed on the light-emitting layer LE. The opposing electrode OE may be formed continuously on the light-emitting layer LE and the partition layer 150 without being patterned.

According to the embodiment, an active protection pattern is formed between an etch-stop layer and an active pattern. Thus, the active pattern may be prevented from being damaged during the process of forming contact openings in the etch-stop layer.

Furthermore, the active protection pattern and the active pattern may be formed in a same photolithography process. Thus, the active protection pattern may be formed without an additional mask.

FIGS. 15 to 25 are cross-sectional views illustrating a method for manufacturing the display substrate according to another example embodiment. In the display substrate, elements having same functions as elements of the display substrate illustrate in FIGS. 4 to 13 include same materials and may be formed through same methods. Thus, any duplicated explanation may be omitted.

Referring to FIG. 15, a first gate metal layer is formed on a base substrate 200 to form a first gate metal pattern including a connection pattern SP and a first capacitor electrode STE1. The first gate metal pattern may further include a signal line such as a gate line, a data line or the like.

A first gate insulation layer 210 is formed to cover the first gate metal pattern.

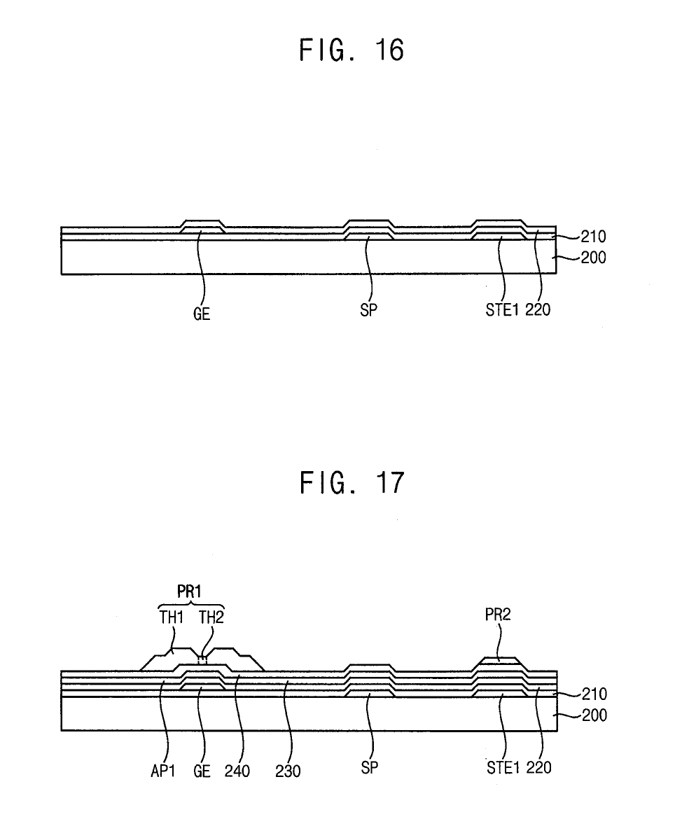

Referring to FIG. 16, a second gate metal layer is formed on the first gate insulation layer 210 and patterned to form a second gate metal pattern including a gate electrode GE.

A second gate insulation layer 220 is formed to cover the second gate metal pattern.

Referring to FIG. 17, an oxide semiconductor layer 230 and an active protection layer 240 are formed on the second gate insulation layer 220.

A first photoresist pattern PR1 and a second photoresist pattern PR2 are formed on the active protection layer 240. The first photoresist patterns PR1 has thickness gradient (e.g., has a variable thickness). For example, the first photoresist patterns PR1 includes a first thickness portion TH1 and a second thickness portion TH2 that is thinner than the first thickness portion TH1. The second photoresist pattern PR2 may have a thickness substantially same as the second thickness portion TH2 of the first photoresist pattern PR1.

The first photoresist pattern PR1 overlaps with the gate electrode GE. The second photoresist pattern PR2 overlaps with the first capacitor electrode STE1.

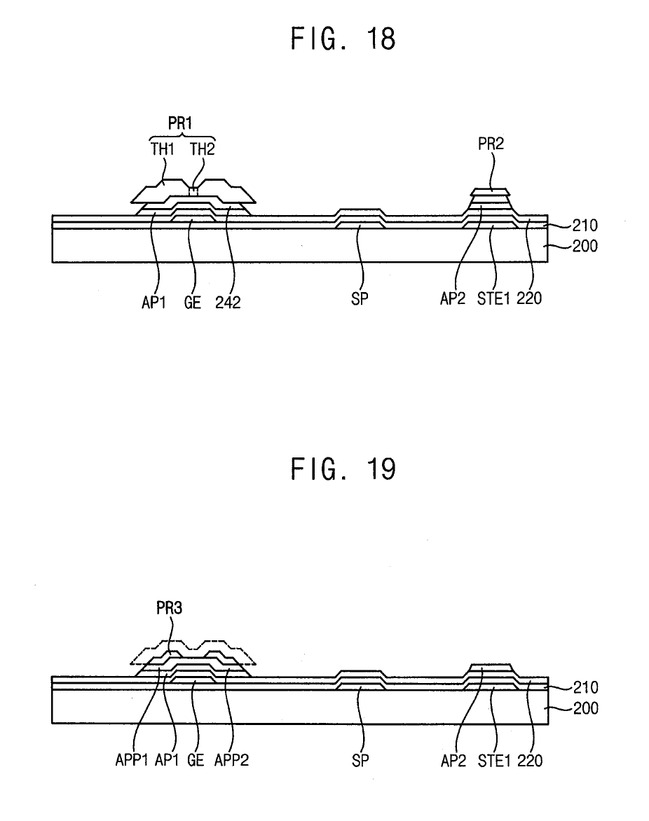

Referring to FIG. 18, the oxide semiconductor layer 230 and the active protection layer 240 are etched by using (utilizing) the first and second photoresist patterns PR1 and PR2 as a mask to form a first active pattern AP1, a second active pattern AP2, and a preliminary active protection pattern 242.

The first active pattern AP1 overlaps with the gate electrode GE. The preliminary active protection pattern 242 is disposed on the first active pattern AP1. The second active pattern AP2 overlaps with the first capacitor electrode STE1.

Referring to FIG.19, through an ashing process, the first photoresist pattern PR1 is partially removed and the second photoresist pattern PR2 is entirely removed. As a result, the second thickness portion TH2 of the first photoresist pattern PR1 is removed, and the first thickness portion TH1 of the first photoresist pattern PR1 partially remains to form a third photoresist pattern PR3.

The third photoresist pattern PR3 partially covers an upper surface of the preliminary active protection pattern 242. Thus, the upper surface of the preliminary active protection pattern 242 is partially exposed. Because the second photoresist pattern PR2 is entirely removed, an upper surface of the active protection layer remaining on the second active pattern AP2 is entirely exposed.

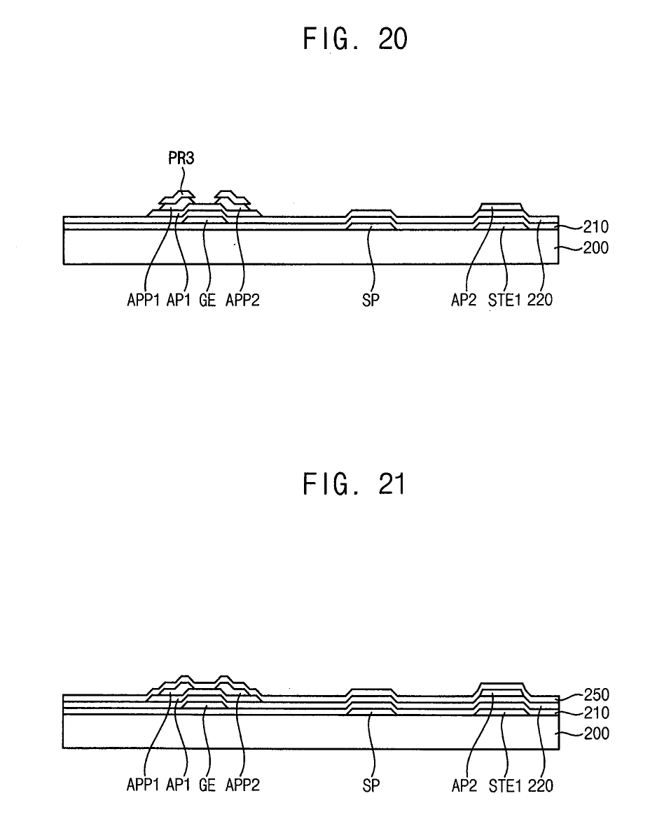

Referring to FIG. 20, the preliminary active protection pattern 242 is patterned by using (utilizing) the third photoresist pattern PR3 as a mask to form a first active protection pattern APP1 and a second active protection pattern APP2. The active protection layer on the second active pattern AP2 is removed so that an upper surface of the second active pattern AP2 is exposed.

The first active protection pattern APP1 and the second active protection pattern APP2 are disposed on the first active pattern AP1 and are spaced from each other.

Referring to FIG. 21, an etch-stop layer 250 is formed to cover the first and second active protection patterns APP1 and APP2. A portion of the etch-stop layer 250 contacts the second gate insulation layer 220.

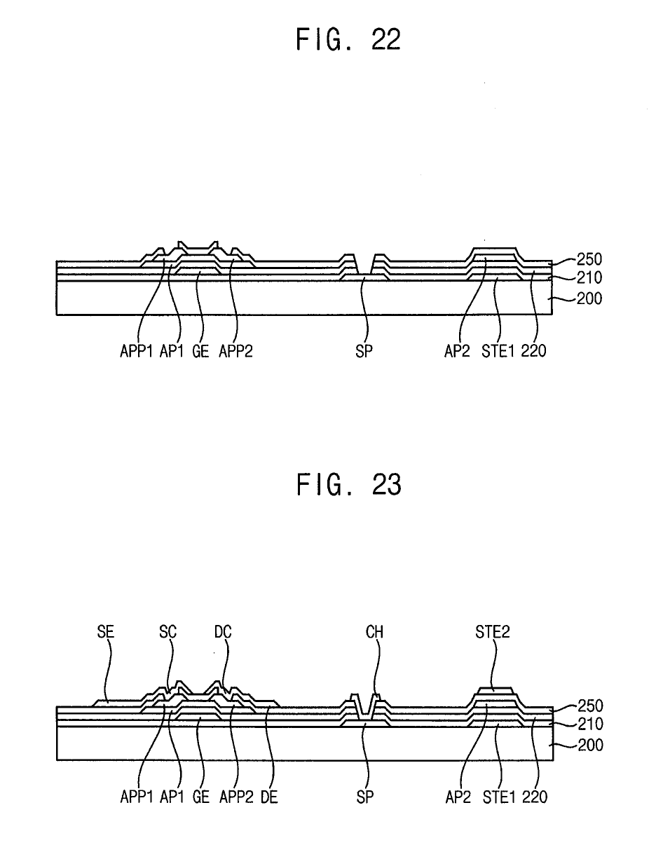

Referring to FIG. 22, the etch-stop layer 250 is patterned to form contact openings (e.g., contact holes) respectively exposing the first and second active protection patterns APP1 and APP2.

In a same process, the etch-stop layer 250, the second gate insulation layer 220, and the gate insulation layer 210 are patterned to expose the connection pattern SP.

In the process of exposing the connection pattern SP, over-etching of the etch-stop layer 250 occurs so that the first and second gate insulation layers 210 and 220 may be etched (e.g., unintentionally etched). Thus, when the active protection patterns APP1 and APP2 do not exist (are not present), the first active pattern AP1 may be damaged. In an embodiment, the active protection patterns APP1 and APP2 are formed on the first active pattern AP1 so that damage to the first active pattern AP1 is prevented.

Referring to FIG. 23, a source metal layer is formed on the etch-stop layer 250 and patterned to form a source metal pattern including a source electrode SE, a drain electrode DE, a contact member CH, and a second capacitor electrode STE2. The source metal pattern may further include a driving line coupled to (e.g., connected, continuously connected to, or integrally formed with) the source electrode SE and the second capacitor electrode STE2.

The source electrode SE and the drain electrode DE respectively contact the first active protection pattern APP1 and the second active protection pattern APP2 through respective contact openings of the etch-stop layer 250.

For example, the source electrode SE includes a source contact SC contacting the first active protection pattern APP1. The drain electrode DE includes a drain contact DC contacting the second active protection pattern APP2.

The second capacitor electrode STE2 is formed on the etch-stop layer 250 and overlaps with the first capacitor electrode STE1 and the second active pattern AP2.

The contact member CH passes through the etch-stop layer 250, the second gate insulation layer 220, and the first gate insulation layer 210 to contact the connection pattern SP.

When the active protection patterns APP1 and APP2 are formed, a channel length of a thin film transistor may be defined by a length between the active protection patterns APP1 and APP2 and is smaller than a length between the source contact SC and the drain contact DC. A thin film transistor may have a reduced channel length which may improve electrical characteristics of the thin film transistor.

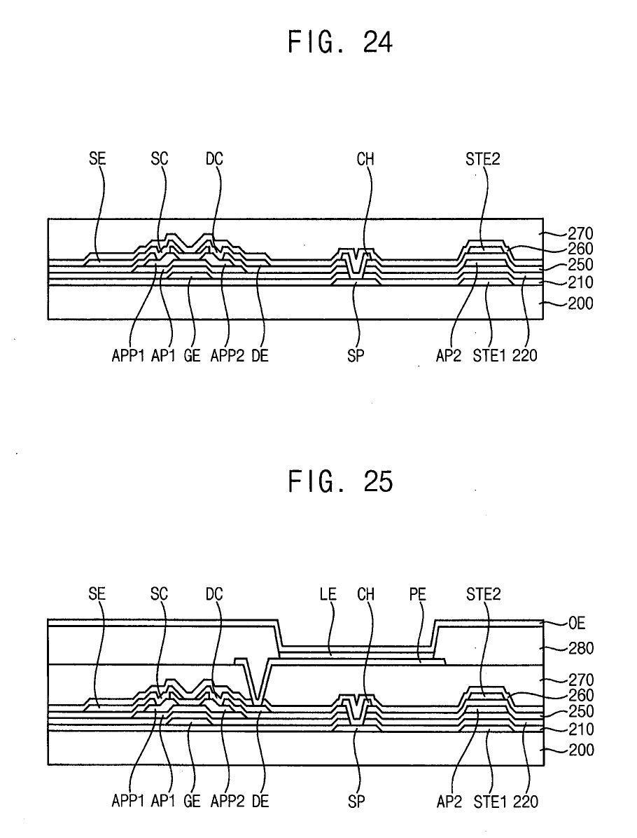

Referring to FIG. 24, a passivation layer 260 is formed to cover the source metal layer. An organic insulation layer 270 is formed on the passivation layer 260.

The passivation layer 260 protects the source metal pattern. The organic insulation layer 270 flattens an upper surface of the substrate.

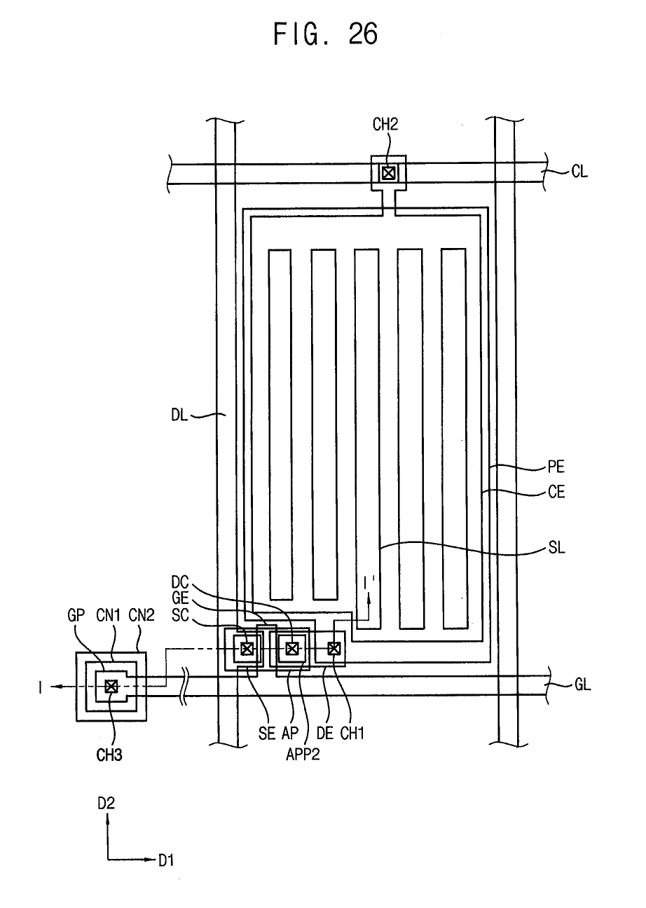

Referring to FIG. 25, the organic insulation layer 270 and the passivation layer 260 are patterned to form a contact opening (e.g., a contact hole) exposing the drain electrode DE.

A pixel electrode layer is formed on the organic insulation layer 270 and patterned to form a pixel electrode PE. The pixel electrode PE contacts the drain electrode DE through the contact opening formed through the organic insulation layer 270 and the passivation layer 260.

A partition layer 280 is formed on the pixel electrode PE and the organic insulation layer 270. The partition layer 280 is patterned to form an opening exposing the pixel electrode PE. The opening may define a pixel area of each pixel unit.

A light-emitting layer LE is formed in the opening. The light-emitting layer LE may include a hole-transferring layer, a hole-injection layer, an organic light-emitting layer, an electron-injection layer, an electron-transferring layer, and may further include various functional layers.

An opposing electrode OE is formed on the light-emitting layer LE. The opposing electrode OE may be formed continuously on the light-emitting layer LE and the partition layer 280 without being patterned.

The display substrate may be used for an organic electroluminescence display device.

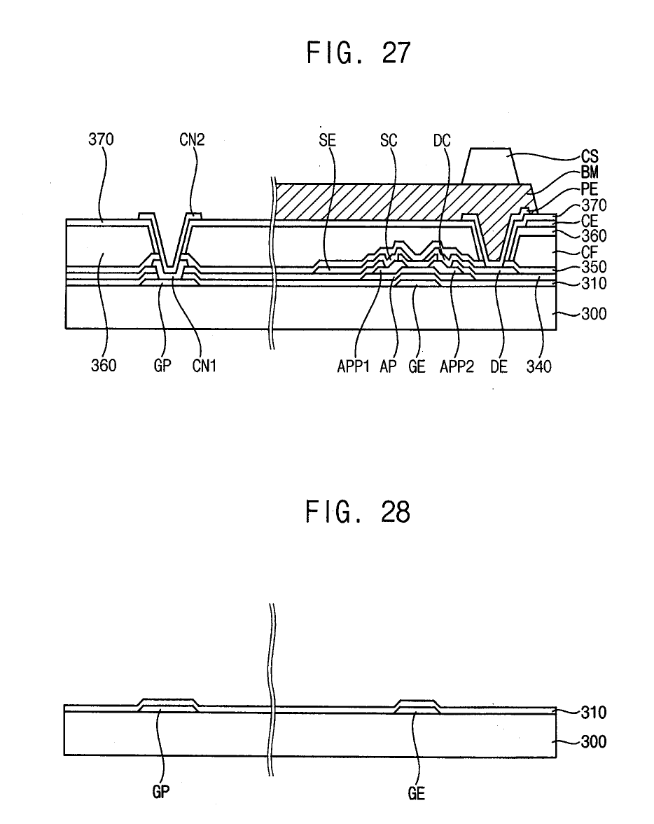

FIG. 26 is a plan view illustrating a display substrate according to another example embodiment. FIG. 27 is a cross-sectional view taken along the line I-I′ of FIG. 26.

Referring to FIGS. 26 and 27, a display substrate includes a base substrate 300, a thin film transistor disposed on the base substrate 300, a pixel electrode PE electrically coupled to the thin film transistor, a common electrode CE overlapping with the pixel electrode PE. The display substrate may further include a color filter CF overlapping with the pixel electrode PE, a black matrix BM overlapping with the thin film transistor, and a column spacer CS overlapping with the thin film transistor. The display substrate may be used for a liquid crystal display device. For example, a liquid crystal display panel may include the display substrate, an opposing substrate facing the display substrate, and a liquid crystal layer between the display substrate and the opposing substrate.

The thin film transistor is electrically coupled to a gate line GL and a data line DL. The thin film transistor includes a gate electrode GE, an active pattern AP, a source electrode SE, and a drain electrode DE.

The gate line GL extends in a first direction D1, and the data line DL extends in a second direction D2, in a plan view. The first direction D1 crosses (e.g., intersects) the second direction D2. For example, the first direction D1 may be substantially perpendicular to the second direction D2.

The gate line GL is electrically coupled to the gate electrode GE. For example, the gate electrode GE may protrude from the gate line GL in the second direction D2. In another embodiment, a portion of the gate line GL may overlap with the first active pattern AP1 to function as the gate electrode GE so that the gate electrode GE may not protrude from the gate line GL.

An end of the gate line GL is connected to a gate pad GP. A gate signal is provided to the gate line GL through the gate pad GP. The gate pad GP contacts a first connection electrode CN1 disposed at a same layer as the source electrode SE and the drain electrode DE. The first connection electrode CN1 contacts a second connection electrode CN2 disposed at a same layer as the pixel electrode PE. The gate pad GP receives a gate signal from a driver, which may be disposed in the display substrate or out of the display substrate, through the first and second connection electrodes CN1 and CN2. In another embodiment, one of the first and second connection electrodes CN1 and CN2 may be omitted. The gate pad GP is disposed at a peripheral area surrounding a display area.

The display substrate further includes a common line CL electrically coupled to the common electrode CE to provide a common voltage to the common electrode CE. The common line CL may be disposed in a same layer as the gate electrode GE and the gate line GL.

The display substrate further includes a gate insulation layer 310 covering the common line CL, the gate electrode GE, and the gate line GL.

The active pattern AP overlaps with the gate electrode GE. The active pattern AP is disposed on the gate insulation layer 310. The active pattern AP includes an oxide semiconductor. When a gate voltage is applied to the gate electrode GE, the active pattern AP becomes a conductor to function as a channel.

The display substrate further includes an etch-stop layer 340 covering the active pattern AP.

The source electrode SE and the drain electrode DE are spaced from each other and are each electrically coupled to the active pattern AP. The source electrode SE and the drain electrode DE are disposed on the etch-stop layer 340.

An active protection pattern is disposed between the active pattern AP and the source electrode SE and/or between the active pattern AP and the drain electrode DE. For example, a first active protection pattern APP1 is disposed between the source electrode SE and the active pattern AP, and a second active protection pattern APP2 is disposed between the drain electrode DE and the active pattern AP. The etch-stop layer 340 has a plurality of contact openings (e.g., contact holes). A source contact SC of the source electrode SE and a drain contact DC of the drain electrode DE respectively contact the first active protection pattern APP1 and the second active protection pattern APP2 through respective contact openings of the etch-stop layer 340.

The first and second active protection patterns APP1 and APP2 are disposed under the etch-stop layer 340. Thus, the active pattern AP is not exposed through the contact openings in the etch-stop layer 340.

The data line DL is electrically coupled to the source electrode SE. For example, the source electrode SE may protrude from the data line DL in the first direction D1. The data line DL may be formed at a same layer as the source electrode SE and the drain electrode DE. In another embodiment, a portion of the data line DL may contact the active pattern AP or the first active protection pattern APP1 to function as the first source electrode SE1 so that the source electrode SE may not protrude from the data line DL.

The display substrate further includes a passivation layer 350 covering the source electrode SE and the drain electrode DE. The color filter CF is disposed on the passivation layer 350. In another embodiment, the color filter CF may be formed on the opposing substrate facing the display substrate (e.g., may be formed on a surface of the opposing substrate that faces the base substrate).

An organic insulation layer 360 is disposed on the color filter CF. The organic insulation layer 360 flattens an upper surface of the display substrate.

The common electrode CE is disposed on the organic insulation layer 360. A pixel insulation layer 370 is disposed on the common electrode CE. The pixel electrode PE is disposed on the pixel insulation layer 370. The common electrode CE includes a second contact portion CH2 passing through the organic insulation layer 360, the passivation layer 350, the etch-stop layer 340, and the gate insulation layer 310 to be coupled to the common line CL. The second contact portion CH2 may be electrically coupled to the common line CL through a connection member that is similar to the second connection electrode CN2.

In an embodiment, the pixel electrode PE is disposed on the common electrode CE. In another embodiment, the pixel electrode PE may be disposed under the common electrode CE. In another embodiment, the common electrode CE may be formed on the opposing substrate facing the display substrate.

The pixel electrode PE is disposed on the pixel insulation layer 370. The pixel electrode PE has a silt portion SL. The slit portion SL may have a shape extending, for example, in the second direction D2. A plurality of slits may be arranged along the first direction D1. The pixel electrode PE overlaps with the common electrode CE to form an electric field depending on a voltage applied thereto so that an arrangement of liquid crystal molecules on the pixel electrode PE is controlled. The pixel electrode PE includes a first contact portion CH1 passing through the pixel insulation layer 370, the organic insulation layer 360, and the passivation layer 350 to contact the drain electrode DE.

The common electrode CE and the pixel electrode PE may include a transparent conductive oxide such as indium zinc oxide, indium tin oxide, or the like.

The black matrix BM blocks a light incident thereon. In order to block a light, the black matrix BM may include black pigment, such as carbon black. The black matrix BM may partially cover the pixel electrode PE and may overlap with the thin film transistor of the display substrate. For example, the black matrix BM may overlap with the first contact portion CH1. In another embodiment, the black matrix BM may be formed on the opposing substrate facing the display substrate. In another embodiment, the black matrix BM may be disposed between a pixel electrode and a passivation layer.

The column spacer CS may be disposed on the black matrix BM and maintains a cell gap between the display substrate and the opposing substrate.

FIGS. 28 to 36 are cross-sectional views illustrating a method for manufacturing the display substrate illustrated in FIGS. 26 and 27.

Referring to FIG. 28, a gate metal layer is formed on a base substrate 300 and patterned to form a gate metal pattern including a gate electrode GE and a gate pad GP. The gate metal pattern may further include a common line and a gate line coupled to (e.g., connected, continuously connected to, or integrally formed with) the gate electrode GE and the gate pad GP.

A gate insulation layer 310 is formed to cover the gate metal pattern.

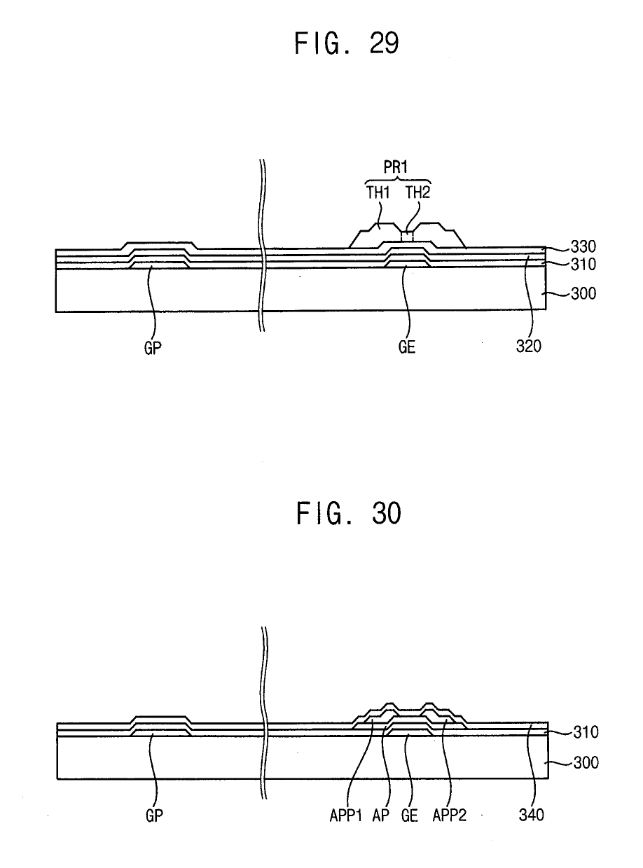

Referring to FIG. 29, an oxide semiconductor layer 320 and an active protection layer 330 are formed on the gate insulation layer 310.

A first photoresist pattern PR1 is formed on the active protection layer 330. The first photoresist patterns PR1 has thickness gradient (e.g., has a variable thickness). For example, the first photoresist patterns PR1 includes a first thickness portion TH1 and a second thickness portion TH2 that is thinner than the first thickness portion TH1. The first photoresist pattern PR1 overlaps with the gate electrode GE.

Referring to FIG. 30, the oxide semiconductor layer 320 and the active protection layer 330 are etched by using (utilizing) the first photoresist pattern PR1 as a mask to form an active pattern AP and a preliminary active protection pattern.

The first photoresist pattern PR1 is partially removed through an ashing process. The preliminary active protection pattern is patterned by using (utilizing) a remaining first photoresist pattern as a mask to form a first active protection pattern APP1 and a second active protection pattern APP2. The first and second active protection patterns APP1 and APP2 are disposed on the active pattern AP and are spaced from each other.

An etch-stop layer 340 is formed to cover the first and second active protection patterns APP1 and APP2. A portion of the etch-stop layer 340 contacts the gate insulation layer 310.

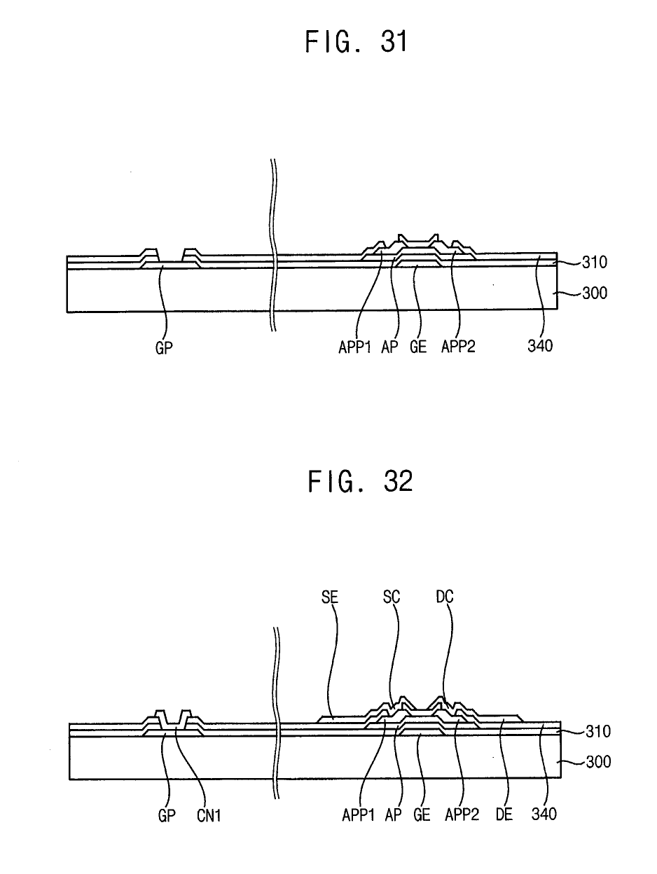

Referring to FIG. 31, the etch-stop layer 340 is patterned to form contact openings (e.g., contact holes) respectively exposing the first and second active protection patterns APP1 and APP2.

In a same process, the etch-stop layer 340 and the gate insulation layer 310 are patterned to expose the gate pad GP.

In the process of exposing the gate pattern GP, over-etching of the etch-stop layer 340 occurs so that the gate insulation layer 310 may be etched (e.g., unintentionally etched). Thus, when the active protection patterns APP1 and APP2 do not exist (e.g., are not formed), the active pattern AP may be damaged. In an embodiment, the active protection patterns APP1 and APP2 are formed on the active pattern AP so that damage to the active pattern AP is prevented.

Referring to FIG. 32, a source metal layer is formed on the etch-stop layer 340 and patterned to form a source metal pattern including a source electrode SE, a drain electrode DE, and a first connection electrode CN1.

The source electrode SE and the drain electrode DE respectively contact the first active protection pattern APP1 and the second active protection pattern APP2 through respective contact openings in the etch-stop layer 340. The first connection electrode CN1 contacts the gate pad GP through the contact opening formed through the etch-stop layer 340 and the gate insulation layer 310.

The source electrode SE includes a source contact SC contacting the first active protection pattern APP1. The drain electrode DE includes a drain contact DC contacting the second active protection pattern APP2.

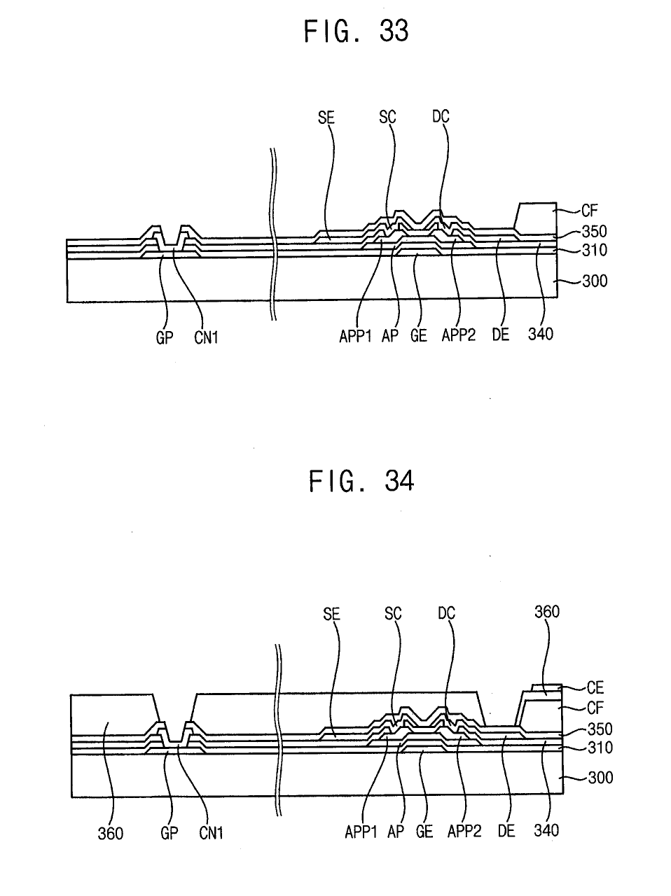

Referring to FIG. 33, a passivation layer 350 is formed to cover the source metal pattern. A color filter CF is formed on the passivation layer 350.

The color filter CF overlaps with a pixel electrode. For example, the color filter CF may include a red color filter, a green color filter, and/or a blue color filter. In another embodiment, the color filter CF may include a red color filter, a green color filter, a blue color filter, and/or a white color filter. In another embodiment, the color filter CF may include a yellow color filter, a cyan color filter, and/or a magenta color filter. The color filters may have sizes different from each other.

Referring to FIG. 34, an organic insulation layer 360 is formed to cover the color filter CF. The organic insulation layer 360 flattens an upper surface of the substrate (e.g., the organic insulation layer 360 has a planar upper surface). The organic insulation layer 360 is patterned to form contact openings (e.g., contact holes). The contact openings may overlap with the drain electrode DE, the gate pad GP, and the common line.

A transparent conductive layer is formed on the organic insulation layer 360 and patterned to form a common electrode CE. The common electrode CE may be electrically coupled to the common line through a contact opening (e.g., a contact hole) formed through the organic insulation layer 360, the passivation layer 350, and the gate insulation layer 310.

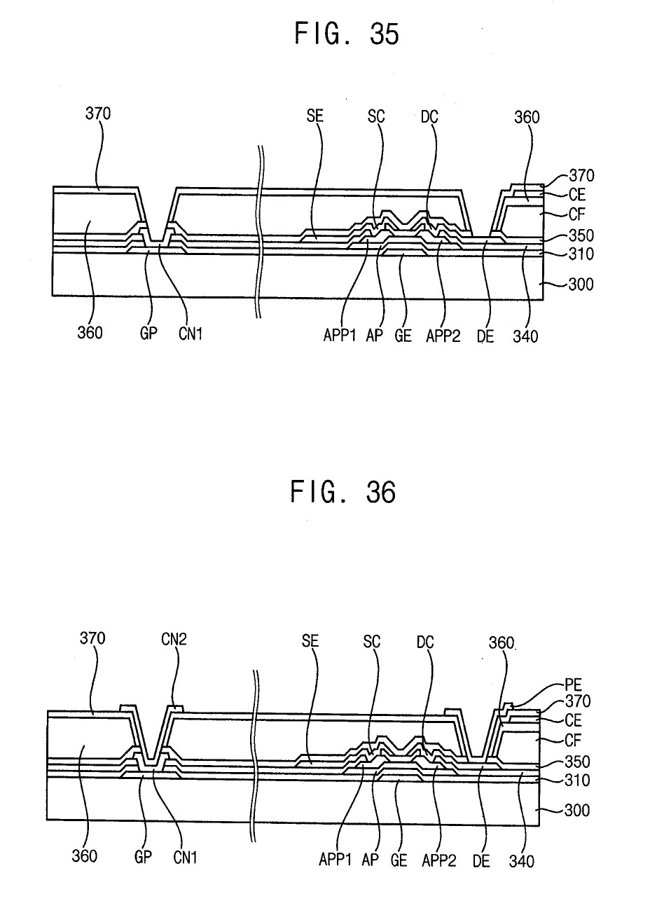

Referring to FIG. 35, after a pixel insulation layer 370 covering the common electrode CE and the organic insulation layer 360 is formed, the pixel insulation layer 370 and the passivation layer 350 are patterned to expose the drain electrode DE and the first connection electrode CN1. In another embodiment, the passivation layer 350 may be patterned before the common electrode CE is formed.

Referring to FIG. 36, a transparent conductive layer is formed on the pixel insulation layer 370 and patterned to form a pixel electrode PE and a second connection electrode CN2.

The pixel electrode PE contacts the drain electrode DE. The second connection electrode CN2 contacts the first connection electrode CN1. The pixel electrode PE has a plurality of slits extending in a direction. The pixel electrode PE overlaps with the color filter CF and the common electrode CE.

Referring to FIG. 27, a black matrix BM is formed to partially overlap with pixel electrode PE. A column spacer CS is formed on the black matrix BM. The black matrix BM and the column spacer CS may be formed through a photolithography process using (utilizing) a composition including a photosensitive material.

Example embodiments may be used for a display device such as a liquid crystal display, an organic electroluminescence display, or the like, for example, a digital television, a monitor connected to a computer, a laptop computer, a mobile game player, a mobile music player, a mobile phone, a navigation device, or the like.

The foregoing is illustrative and is not to be construed as limiting thereof. Although a few example embodiments have been described herein, those skilled in the art will readily appreciate that many modifications are possible in these example embodiments without materially departing from the novel teachings, aspects, and features of the invention. Accordingly, all such modifications are intended to be included within the scope of this disclosure. In the claims, any means-plus-function clauses are intended to cover the structures described herein as performing the recited function and not only structural equivalents but also equivalent structures. Therefore, it is to be understood that the foregoing is illustrative and is not to be construed as limited to the specific example embodiments disclosed, and modifications to the disclosed example embodiments, as well as other embodiments, are intended to be included within the scope of the disclosure, including the appended claims and their equivalents.

What is claimed is:

1. A thin film transistor comprising:
a gate electrode;
an active pattern over the gate electrode and comprising an oxide semiconductor;
an etch-stop layer covering the active pattern;
a source electrode on the etch-stop layer;
a drain electrode on the etch-stop layer and spaced from the source electrode; and
an active protection pattern between the etch-stop layer and the active pattern and electrically coupled to the source electrode and the drain electrode.

2. The thin film transistor of claim 1, wherein the active protection pattern comprises a conductive oxide.

3. The thin film transistor of claim 2, wherein the active pattern covers an entire lower surface of the active protection pattern.

4. The thin film transistor of claim 1, wherein the active protection pattern comprises:
a first active protection pattern over the source electrode; and
a second active protection pattern over the drain electrode.

5. The thin film transistor of claim 4, wherein the source electrode comprises a source contact extending through the etch-stop layer to contact the first active protection pattern,
the drain electrode comprises a drain contact extending through the etch-stop layer to contact the second active protection pattern, and
a distance between the first active protection pattern and the second active protection pattern is smaller than a distance between the source contact and the drain contact.

6. A display substrate comprising:
a gate line on a base substrate;
a data line crossing the gate line;
a first gate electrode electrically coupled to the gate line;
a first active pattern over the first gate electrode and comprising an oxide semiconductor;
an etch-stop layer covering the first active pattern;
a first source electrode on the etch-stop layer and electrically coupled to the data line;
a first drain electrode on the etch-stop layer and spaced from the first source electrode; and
an active protection pattern between the etch-stop layer and the active pattern and electrically coupled to the first source electrode and the first drain electrode.

7. The display substrate of claim 6, wherein the active protection pattern comprises a conductive oxide.

8. The display substrate of claim 6, wherein the first active pattern covers an entire lower surface of the active protection pattern.

9. The display substrate of claim 6, wherein the active protection pattern comprises:
a first active protection pattern over the first source electrode; and
a second active protection pattern over the first drain electrode.

10. The display substrate of claim 9, wherein the first source electrode comprises a first source contact extending through the etch-stop layer to contact the first active protection pattern,
the first drain electrode comprises a first drain contact extending through the etch-stop layer to contact the second active protection pattern, and
a distance between the first active protection pattern and the second active protection pattern is smaller than a distance between the first source contact and the first drain contact.

11. The display substrate of claim 9, further comprising:
a second gate electrode electrically coupled to the first drain electrode;
a second active pattern over the second gate electrode and comprising an oxide semiconductor;
a second source electrode on the etch-stop layer;
a second drain electrode spaced from the source electrode;
a third active protection pattern over the second source electrode;
a fourth active protection pattern over the second drain electrode;
a passivation layer covering the first source electrode, the first drain electrode, the second source electrode, and the second drain electrode; and
a pixel electrode electrically coupled to the second drain electrode.

12. The display substrate of claim 11, further comprising:
a first capacitor electrode coupled to the first drain electrode and the second gate electrode; and
a second capacitor electrode over the first capacitor electrode and coupled to the second source electrode.

13. The display substrate of claim 12, further comprising:
a partition layer on the pixel electrode and having an opening over the pixel electrode;
a light-emitting layer on the pixel electrode in the opening; and
an opposing electrode on the light-emitting layer.

14. The display substrate of claim 9, further comprising:
a connection pattern on the base substrate;
a first gate insulation layer covering the connection pattern;
a second gate insulation layer covering the first gate electrode; and
a contact member at a same layer as the first source electrode and extending through the etch-stop layer, the first gate insulation layer, and the second gate insulation layer to contact the connection pattern.

15. The display substrate of claim 9, further comprising:
a gate pad coupled to an end of the gate line;
a gate insulation layer covering the gate pad; and
a connection electrode extending through the etch-stop layer and the gate insulation layer to contact the gate pad.

16. A method for manufacturing a display substrate, the method comprising:
forming a gate metal pattern on a base substrate, the gate metal pattern comprising a gate electrode;
forming a gate insulation layer covering the gate metal pattern;
forming an active pattern and an active protection pattern on the gate insulation layer, the active pattern comprising an oxide semiconductor, the active protection pattern being on the active pattern;
forming an etch-stop layer covering the active protection pattern;
patterning the etch-stop layer to expose the active protection pattern; and
forming a source metal pattern, comprising a source electrode and a drain electrode, to contact the active protection pattern.

17. The method of claim 16, wherein the active protection pattern comprises a conductive oxide.

18. The method of claim 17, wherein the forming of the active pattern and the active protection pattern comprises:
forming an oxide semiconductor layer and an active protection layer on the gate insulation layer;
forming a first photoresist pattern on the active protection layer, the first photoresist pattern comprising a first thickness portion and a second thickness portion thinner than the first thickness portion;
etching the oxide semiconductor layer and the active protection layer utilizing the first photoresist pattern as a mask to form the active pattern and a preliminary active protection pattern;
removing a portion of the first photoresist pattern to form a second photoresist pattern; and
etching the preliminary active protection pattern by utilizing the second photoresist pattern as a mask to form the active protection pattern comprising a first active protection pattern and a second active protection pattern spaced from the first active protection pattern.

19. The method of claim 16, wherein the gate metal pattern further comprises a first capacitor electrode coupled to the drain electrode, and
the etch-stop layer and the gate insulation layer are etched to expose the first capacitor electrode and the active protection pattern.

20. The method of claim 19, wherein the source metal pattern further comprises a second capacitor electrode over the first capacitor electrode.
